(19) United States
(12) Patent Application Publication
(10) Pub. No.: US 2026/0072080 A1
(43) Pub. Date: Mar. 12, 2026

(54) PULSE ELECTRON MICROSCOPE DEVICE AND INSPECTION METHOD USING THE SAME

(71) Applicant: Samsung Electronics Co., Ltd., Suwon-si (KR)

(72) Inventors: Bumjoo Lee, Suwon-si (KR); Jinwoo Lee, Suwon-si (KR); YUSIN YANG, Suwon-si (KR); JEONG HOI KIM, Suwon-si (KR); HONGCHE NOH, Suwon-si (KR); JONG CHEON SUN, Suwon-si (KR); SUYOUNG LEE, Suwon-si (KR)

(21) Appl. No.: 19/063,396

(22) Filed: Feb. 26, 2025

(30) Foreign Application Priority Data
Sep. 6, 2024 (KR) 10-2024-0121424

(51) Int. Cl. G01R 31/307

(52) U.S. Cl. CPC G01R 31/307

(57) ABSTRACT

An embodiment of the present disclosure provides a pulse electron microscope device including: a pulse generator configured to emit a laser pulse; a first beam splitter configured to split the laser pulse into a first laser pulse and a second laser pulse; a second beam splitter configured to split the second laser pulse and to reflect a second-1 laser pulse; an interval controller configured to control a time interval between the first laser pulse and the second-1 laser pulse by controlling an optical path length of the first laser pulse; a column part including a photocathode, the photocathode configured to convert the first laser pulse into a first electron pulse and convert the second-1 laser pulse into a second electron pulse; and an inspection module configured to inspect electrical defects in the sample by detecting a change in potential occurring on a surface of the sample.

### CROSS-REFERENCE TO RELATED APPLICATION

This application claims priority to and the benefit of Korean Patent Application No. 10-2024-0121424, filed in the Korean Intellectual Property Office on Sep. 6, 2024, the entire contents of which are incorporated herein by reference.

### BACKGROUND

### (a) Field of the Invention

The present disclosure relates to a pulse electron microscope device and an inspection method using the same.

### (b) Description of the Related Art

In a semiconductor manufacturing process, there is a process of producing products from raw materials, and an inspection process of inspecting products for defects during the production process. Although a process of producing a product is important, a measurement and inspection (MI) process is also important to minimize product defects and improve yield.

As advancement of microprocessing technology for memory semiconductors accelerates, it is becoming more difficult to detect defects in products. Accordingly, as a speed of product production slows down, resulting in lower yields, importance of the measurement and inspection (MI) process of a product is increasing.

The measurement and inspection (MI) process is used to verify that physical and electrical characteristic targets of a semiconductor device being produced are properly met at each stage of a manufacturing sequence. Typically, a scanning electron microscope (SEM) is used to conduct electrical characteristic-based inspection of semiconductor devices.

The scanning electron microscope (SEM) is an electron microscope that images a surface of a target sample by scanning it with an electron beam. An inspection method using an electron beam may detect defects under a surface of a sample by measuring a change in voltage contrast (VC) resulting from an electrical effect of “killer” defects, e.g., “open” and “short” type defects, and may identify semiconductor defects based on the change in voltage contrast (VC).

### SUMMARY

Embodiments of the present disclosure have been proposed to solve the above problems, and conventional defect inspection methods using electron beams may only detect defects that produce strong signals, such as defects in which a circuit is completely disconnected. According to the present disclosure, a defect that has occurred may be detected without limitation on a degree of disconnection of the defect by utilizing a photocathode and two laser pulses and controlling an interval between the laser pulses. In particular, the present disclosure attempts to provide a pulse electron microscope device and an inspection method using the same, capable of improving an efficiency of a semiconductor defect determination process by enabling high-speed inspection without speed reduction, compared to inspection using a conventional electron beam, by fixing a time interval between pulses.

Furthermore, the present disclosure attempts to provide a pulse electron microscope device and an inspection method using the same, capable of maximum speed inspection by setting a pulse repetition rate (Hz) and a scan rate (Hz), which is a speed at which a scanner of an inspection module acquires pixels, to be the same.

An embodiment of the present disclosure provides a pulse electron microscope device including: a pulse generator configured to emit a source laser pulse; a first beam splitter configured to split the source laser pulse into a first laser pulse and a second laser pulse; a second beam splitter configured to split the second laser pulse and to reflect a second-1 laser pulse, which is included in the split second laser pulse; an interval controller configured to control a time interval between the first laser pulse and the second-1 laser pulse by controlling an optical path length of the first laser pulse; a column part including a photocathode, the photocathode configured to convert the first laser pulse into a first electron pulse and convert the second-1 laser pulse into a second electron pulse, and focus the first electron pulse and the second electron pulse onto a sample; and an inspection module configured to identify electrical defects in the sample by detecting a change in potential occurring on a surface of the sample as a result of the first electron pulse and the second electron pulse.

An embodiment of the present disclosure provides a pulse electron microscope device including: a pulse generator configured to emit a source laser pulse; a first beam splitter configured to split the source laser pulse into a first laser pulse and a second laser pulse; a second beam splitter configured to split the second laser pulse into a third laser pulse and a fourth laser pulse; a column part including a photocathode that converts the first laser pulse into a first electron pulse and the third laser pulse into a second electron pulse, and configured to focus the first electron pulse and the second electron pulse on a sample; an interval controller configured to cause the first laser pulse to be incident on the photocathode and control an optical path length of the first laser pulse to cause a delay for a time that the first laser pulse is incident on and irradiates the photocathode such that the first electron pulse is focused on and irradiates the sample at a time point when a change in surface potential of the sample as a result of the second electron pulse is at a maximum; a synchronizer configured to focus the fourth laser pulse onto the sample; and an inspection module configured to identify electrical defects in the sample by detecting a change in potential occurring on a surface of the sample as a result of the first electron pulse and the second electron pulse.

An embodiment of the present disclosure provides an inspection method including: splitting, by a first beam splitter, a source laser pulse emitted from a pulse generator into a first laser pulse and a second laser pulse; adjusting, by an interval controller, an optical path length of the first laser pulse; splitting, by a second beam splitter, the second laser pulse into a third laser pulse and a fourth laser pulse, and reflecting, by the second beam splitter, the third laser pulse to be incident on and irradiate a photocathode; causing a first laser pulse passing through the interval controller to be incident on and irradiate the photocathode at a set time interval from the third laser pulse; converting, by the photocathode, the first laser pulse and the third laser pulse into a first electron pulse and a second electron pulse, respectively, and focusing them on a sample; and inspecting, by an inspection module, an electrical defect in the sample by detecting a change in potential occurring on a surface of a sample during a process of scanning the sample.

According to the embodiments, semiconductor defect inspection may be performed using a column of an existing scanning electron microscope (SEM), thereby minimizing speed loss compared to the existing method and enabling inspection to be performed at a high speed.

### BRIEF DESCRIPTION OF THE DRAWINGS

FIG. 1 illustrates a view showing a pulse electron microscope device according to an embodiment.

FIG. 2 illustrates a view showing a configuration of the pulse electron microscope device according to FIG. 1.

FIG. 3 illustrates a view showing a configuration of a pulse electron microscope device according to another embodiment.

FIG. 4 illustrates a view showing a configuration of the pulse electron microscope device according to FIG. 3.

FIGS. 5A and 5B illustrate views showing a process of inspecting a sample for defects using the pulse electron microscope device according to FIG. 1.

FIGS. 6A and 6B illustrate views showing a process of inspecting a sample for defects using a conventional pulse electron microscope device.

FIG. 7 illustrates a view showing a process of inspecting a sample for defects using the pulse electron microscope device according to FIG. 3.

FIG. 8 illustrates a view showing an inspection method using the pulse electron microscope device according to FIG. 1.

FIG. 9 to FIG. 11 illustrate views showing an inspection method using the pulse electron microscope device according to FIG. 3.

### DETAILED DESCRIPTION

The present disclosure will be described more fully hereinafter with reference to the accompanying drawings, in which embodiments are shown. The invention may, however, be embodied in many different forms and should not be construed as limited to the example embodiments set forth herein. It should also be emphasized that the disclosure provides details of alternative examples, but such listing of alternatives is not exhaustive. Furthermore, any consistency of detail between various examples should not be interpreted as requiring such detail. As those skilled in the art would realize, the described embodiments may be modified in various different ways, and the language of the claims should be referenced in determining the requirements of the invention.

To clearly describe the present disclosure, parts that may be irrelevant to the inventive concept or irrelevant to the description of the drawings may be omitted, and like numerals refer to like or similar constituent elements throughout the specification.

Further, since sizes and thicknesses of constituent members shown in the accompanying drawings are arbitrarily given for better understanding and ease of description, the present disclosure is not limited to the illustrated sizes and thicknesses. In the drawings, the thicknesses of layers, films, panels, regions, etc., are exaggerated for clarity. In the drawings, for better understanding and ease of description, the thicknesses of some layers and areas are exaggerated.

Throughout this specification and the claims that follow, when it is described that an element is “coupled/connected” to another element, the element may be “directly coupled/connected” to the other element or “indirectly coupled/connected” to the other element through a third element. In addition, unless explicitly described to the contrary, the word “comprise” and variations such as “comprises” or “comprising” will be understood to imply the inclusion of stated elements but not the exclusion of any other elements.

It will be understood that when an element such as a layer, film, region, plate, etc. is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion and does not necessarily mean positioned on the upper side of the object portion based on a gravitational direction.

Furthermore, in describing components of embodiments according to the present disclosure, ordinal numbers such as “first,” “second,” “third,” and symbols such as (a), (b), etc. etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim. The labels are not intended to limit the order or sequence of the components.

In the following description, a controller may be a processor (i.e., a hardware circuit), such as a microprocessor, a CPU (Central Processing Unit), a GPU (graphics processor), a digital signal processor (DSP), a field-programmable gate array (FPGA), etc., and may be part of a computer. Such a controller may be formed by several interconnected controllers and may be configured by software. The controller may implement the software to perform various functions, such as controlling another component. As such, the controller may include various input/output interfaces for communicating with other components. The software configuring the controller may be stored in memory and executed by the processor to carry out steps, functions, acts, etc. of a process or method and may implement the described functionality of a component.

In a process of inspecting for defects in semiconductor devices being produced, a scanning electron microscope (SEM) may be used.

When an electron beam is radiated onto a surface of a sample in a scanning electron microscope (SEM), electrons may collide with the surface of the sample and bounce off (e.g., be reflected or scattered), which may be analyzed to conduct an inspection based on electrical characteristics.

As such, an inspection method using an electron beam may detect defects under a surface of a sample by measuring a change in voltage contrast (VC) resulting from an electrical effect of “killer” defects, e.g., “open” and “short” type defects in a semiconductor contact, and may identify semiconductor defects based on this detection.

However, when detecting defects by measuring changes in voltage contrast (VC) using a conventional electron beam, only defects that are measured as strong signals may be detected, such as defects in which a circuit is completely disconnected. Thus, there is a limitation in that defects in which a circuit is vaguely disconnected (e.g., a partial disconnection) may not be detected.

According to the present disclosure, it may be possible to detect additional or all defects and identify the semiconductor defects without being limited to a degree of disconnection of the defects, thereby increasing a semiconductor production yield.

Hereinafter, the pulse electron microscope device 100 and an inspection method using the same according to an embodiment of the present disclosure will be described in more detail with reference to the drawings.

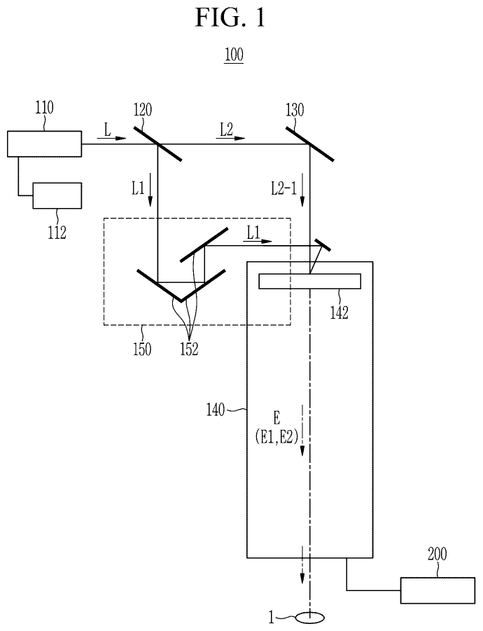

FIG. 1 illustrates a view showing a pulse electron microscope device according to an embodiment, and

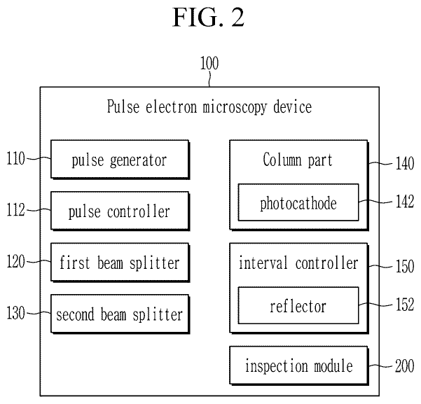

FIG. 2 illustrates a view showing a configuration of the pulse electron microscope device according to FIG. 1.

As illustrated in FIGS. 1 and 2, the pulse electron microscope device 100 according to the present disclosure may include a pulse generator 110, a first beam splitter 120, a second beam splitter 130, a column part 140 including a photocathode 142, an interval controller 150, and an inspection module 200. The column part 140 may be a photocathode electron gun.

The pulse generator 110 may be a laser pulse generator. The laser pulse generator may be a conventional laser pulse generator. The pulse generator may emit a source laser pulse L.

The first beam splitter 120 may split the source laser pulse L emitted from the pulse generator 110 into a first laser pulse L1 and a second laser pulse L2. A beam splitter may have a partially reflective source that reflects a portion of a light beam and transmits the remaining portion of the light beam through the beam splitter to produce two separate light beams.

The column part 140 may include the photocathode 142. The photocathode 142 may be comprised of a material engineered to convert photons (e.g., photons constituting a laser pulse) into electrons using the photoelectric effect. The photocathode 142 may convert the incident first laser pulse L1 and a second-1 laser pulse L2-1 (described below) into a first electron pulse E1 and a second electron pulse E2. The first electron pulse E1 and the second electron pulse E2 emitted from the photocathode 142 may be focused on the sample 1 by a lens (not shown) inside the column part 140.

The second beam splitter 130 may split the second laser pulse L2 transferred from the first beam splitter 120. A portion of the second laser pulse L2 may be transmitted through the second beam splitter 130, and a remaining portion is reflected from the second beam splitter 130 to the photocathode 142.

The portion of the second laser pulse L2 that is reflected and transferred to the photocathode 142 may be called a second-1 laser pulse L2-1.

The second beam splitter 130 may reflect the second-1 laser pulse L2-1 to the photocathode 142. For example, the second-1 laser pulse L2-1 may be reflected by the second beam splitter 130 to be incident on the photocathode 142.

The interval controller 150 may be positioned in an optical path along which the first laser pulse L1 reflected from the first beam splitter 120 travels. The interval controller 150 adjusts the optical path length along which the first laser pulse L1 reflected by the first beam splitter 120 is incident on the photocathode 142. For example, the interval controller 150 may control a time interval Δt between the time the first laser pulse L1 irradiates the photocathode 142 and the time the second-1 laser pulse L2-1 irradiates the photocathode 142 by controlling an optical path length of the first laser pulse L1. The optical path length may be changed by adjusting a physical length of the optical path, or may be changed by adjusting the index of refraction of a material in the optical path. For example, a material having a higher index of refraction may transmit a laser pulse slower resulting in an effectively longer optical path length.

The inspection module 200 may inspect for electrical defects in a sample 1 by detecting an electrical potential change occurring on a surface of the sample 1. The inspection module 200 may use conventional techniques for detecting the electrical potential change.

Referring to FIG. 1, the first beam splitter 120 may be positioned in the optical path of the source laser pulse L emitted from the pulse generator 110.

Some (e.g., the first laser pulse L1) of the source laser pulse L incident on the first beam splitter 120 may be reflected by the first beam splitter 120 to be directed toward a direction in which the interval controller 150 is positioned.

Among the source laser pulses L, the remainder (e.g., the second laser pulse L2) excluding the first laser pulse L1 may pass through the first beam splitter 120 to be directed toward the second beam splitter 130. Some (e.g., the second-1 laser pulse L2-1) of the second laser pulse L2 incident on the second beam splitter 130 may be reflected by the second beam splitter 130 to be directed toward a direction in which the photocathode 142 is positioned.

The first laser pulse L1 split from the source laser pulse L by the first beam splitter 120 may be incident on the interval controller 150.

The interval controller 150 may control the optical path length of the first laser pulse L1 by reflecting the first laser pulse to increase the physical distance the first laser pulse travels and may include a reflector 152, as illustrated in FIG. 1.

Referring to FIG. 1, the interval controller 150 may have a structure that includes a plurality of reflectors 152. The interval controller 150 may adjust an optical path length along which the first laser pulse L1 travels by adjusting (moving) positions of at least one of a plurality of reflectors 152. The position of the reflectors 152 may be adjusted by a linear actuator which may be controlled by a controller to move a reflector 152 to a specific position.

As the optical path length of the first laser pulse L1 increases within the interval controller 150, the amount of time for before the first laser pulse L1 irradiates the photocathode 142 after entering the interval controller 150 increases (e.g., the interval controller 150 may delay the first laser pulse L1).

Accordingly, a time interval Δt may occur between a time point when the first laser pulse L1 that is split from the source laser pulse L by the first beam splitter 120 and incident on the interval controller 150 irradiates the photocathode 142 and a time point when the second-1 laser pulse L2-1 that is reflected from the second beam splitter 130 irradiates the photocathode 142 (e.g., the first laser pulse L1 may irradiate the photocathode 142 after the second-1 laser pulse by the time interval Δt).

The time interval Δt at which the first laser pulse L1 and the second-1 laser pulse L2-1 irradiate the photocathode 142 may be the same as a time interval Δt between the first electron pulse E1 and the second electron pulse E2 emitted from the photocathode 142. Furthermore, a time interval Δt between time points at which the first electron pulse E1 and the second electron pulse E2 are focused on and irradiate the sample 1 may also have the same value.

For example, the interval controller 150 may play a role in controlling the time interval Δt between the first electron pulse E1 and the second electron pulse E2 focused on the sample 1.

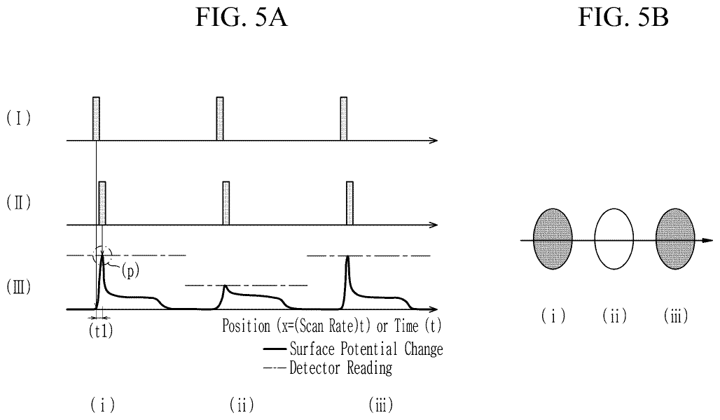

Referring to the graph of FIG. 5A, which described in detail below, the interval controller 150 may control the time interval Δt between the first electron pulse E1 and the second electron pulse E2 such that the first electron pulse E1 (II) is focused on the sample 1 at a time point p when a change in surface potential of the sample 1 is at a maximum by the action of the second electron pulse E2 (I), which irradiates the sample 1 prior to the first electron pulse E1.

For example, the interval controller 150 may be configured to set the time interval Δt to correspond to the time point p which is a maximum of the action of the second electron pulse E2. Assuming that the first electron pulse E1 is focused on and irradiates the sample 1 at the time point p, a value of the time interval Δt between the first electron pulse E1 and the second electron pulse E2 is assumed to be t1.

The interval controller 150 may fix the time interval Δt to a specific time value t1 such that the first electron pulse E1 and the second electron pulse E2 are each focused on and irradiate the sample 1 at a time point when a defect contrast of the sample 1 is at a maximum, as in (III) of FIG. 5A. For example, the interval controller 150 may be to fix the time interval Δt to the value t1.

The pulse electron microscope device 100 may further include a pulse controller 112. The pulse controller 112 may control an amount of charge of the source laser pulse L emitted from the pulse generator 110. For example, the pulse controller 112 may control the amount of energy used to generate the source laser pulse L. The pulse controller 112 may further control how often the laser pulse is generated. The pulse controller 112 may control a power of the laser pulse (L) to maximize a defect contrast of a target sample to be inspected.

The control of the charge amount in the source laser pulse can be achieved through various methods.

The methods include adjusting the pulse energy, power, time, or the physical conditions of the laser. For example, pulse energy can be adjusted through Pulse Width Modulation (PWM) and pulse repetition frequency control. Pulse repetition frequency control indirectly adjusts the energy density and charge amount of each pulse, and as the repetition frequency increases, the amount of charge accumulated may vary. Alternatively, the source laser pulse intensity or energy can be controlled by adjusting the voltage. The pulse controller can also adjust the charge amount using various methods in addition to those described above.

The column part 140 may have a structure and may operate similar to a general scanning electron microscope (SEM) or an inspection device using an electron beam, with the exception that it includes the photocathode 142. Accordingly, a description of a general structure (lens, etc.) within the column part 140 may be omitted.

The scanning electron microscope (SEM) that generally uses an electron beam will be as described below. In this example, the SEM typically uses a filament type electron gun, in which may emit a continuous electron beam. When a voltage is applied to the electron gun, electrons may be emitted from a filament, and a series of electron bundles are accelerated toward the sample by an electric field applied to an anode. Among the electron bundles, those that pass through a hole of an aperture may be focused by a magnetic lens using a magnetic field, forming an electron beam with a constant (monochromatic) wavelength.

This electron beam may then be focused on a specimen by an objective lens using a magnetic field, and if aberration occurs during this process, it may be adjusted using a stigmator.

Electrons incident on the specimen in this way may interact with atoms and electrons contained within the specimen, resulting in secondary electrons (SE), backscattered electrons (BSE), etc. being emitted from the specimen.

It may be common to use a detector to capture emitted electrons, convert them into digital signals, analyze the converted digital signals to create images, and then use the images in an inspection process.

The column part 140 according to the present disclosure may be different from a general scanning electron microscope SEM in that, instead of emitting electrons from a filament type electron gun, the photocathode 142 converts and emits the first laser pulse L1 and the second-1 laser pulse L2-1 to be incident on the photocathode 142 into the first electron pulse E1 and the second electron pulse E2, respectively.

Other structures may be the same as or substantially the same as the structure and principle using a general electron beam, and in the present disclosure, the first electron pulse E1 and the second electron pulse E2 emitted from the photocathode 142 may pass through general structures arranged in the column part 140 to be focused on the sample 1.

Similarly, the first electron pulse E1 and the second electron pulse E2 focused on the sample 1 may interact with atoms contained in the sample 1, resulting in secondary electrons (SE), backscattered electrons (BSE), etc. being emitted from the specimen. The emitted electrons are captured using a detector, converted into a digital signal, analyzed and imaged, and then output to a monitor so that they may be used during an inspection process.

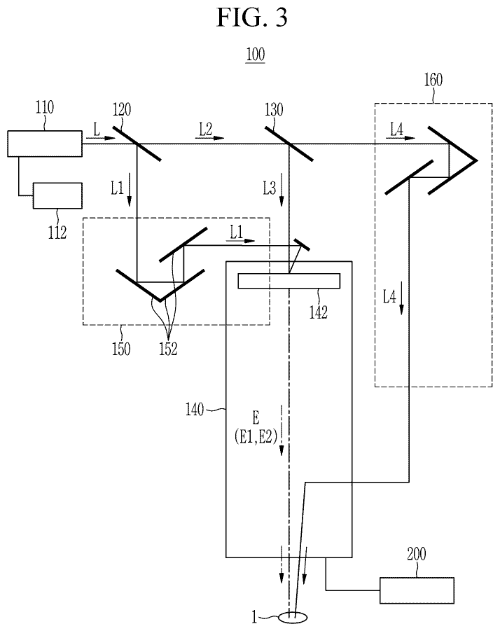

FIG. 3 illustrates a view showing a pulse electron microscope device according to another embodiment, and

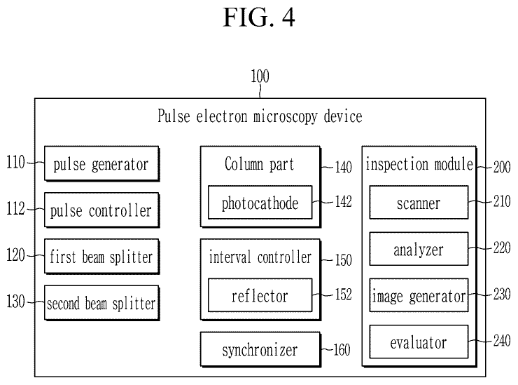

FIG. 4 illustrates a view showing a configuration of the pulse electron microscope device according to FIG. 3.

As illustrated in FIGS. 3 and 4, the pulse electron microscope device 100 according to the present disclosure may further include a synchronizer 160 in addition to the pulse electron microscope device 100 described above.

The pulse electron microscope device 100 may include a pulse generator 110 that emits a laser pulse L, a first beam splitter 120 that splits the source laser pulse L into a first laser pulse L1 and a second laser pulse L2, a second beam splitter 130 that splits the second laser pulse L2 split from source laser pulse L by the first beam splitter 120 into a third laser pulse L3 and a fourth laser pulse L4, a column part 140 including a photocathode 142 that receives the first laser pulse L1 and the third laser pulse L3, converts the laser pulses into a first electron pulse E1 and a second electron pulse E2, respectively, and focuses the electron pulses on the sample 1, an interval controller 150 that causes the first laser pulse L1 split from the source laser pulse L by the first beam splitter 120 to be incident on the photocathode 142 and focuses the first electron pulse E1 on the sample 1 at a time point when a change in surface potential of the sample 1 by the second electron pulse E2, which arrives first, is at a maximum, by controlling an optical path length of the first laser pulse L1, and an inspection module 200 that inspects electrical defects in the sample 1 by detecting the change in surface potential of the sample 1 resulting from the first electron pulse E1 and the second electron pulse E2.

According to FIG. 3 and FIG. 4, the pulse electron microscope device 100 may further include the synchronizer 160. The synchronizer 160 may focus the fourth laser pulse L4 that has passed through the second beam splitter 130 onto a same area of the sample 1 where the first electron pulse E1 is focused. As illustrated in FIG. 3, the synchronizer 160 may be positioned in an optical path of the fourth laser pulse L4.

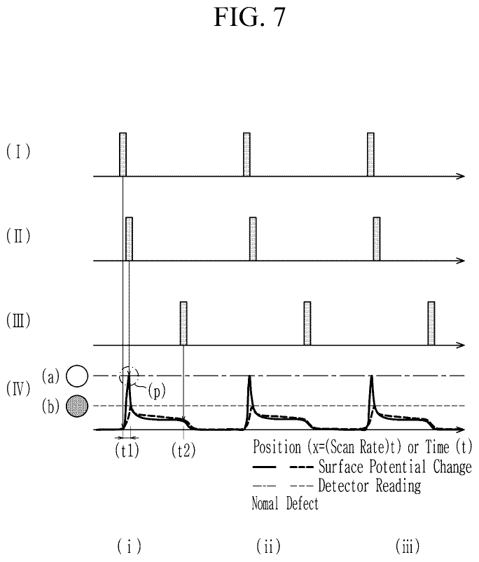

Referring to a graph of FIG. 7 to be described below, the interval controller 150 may control a value of the time interval Δt between the first electron pulse E1 and the second electron pulse E2 to t1 such that the first electron pulse E1 (II) is focused on the sample 1 at a time point p when a change in surface potential of the sample 1 is maximum by the action of a previously emitted second electron pulse E2 (I).

(III) shows an example of irradiating the fourth laser pulse L4 in the synchronizer 160. Referring to (III) and (IV), the synchronizer 160 may cause the fourth laser pulse L4 to be focused on the same area of the sample 1 where the first electron pulse E1 is focused after a certain period of time after the first electron pulse E1 is irradiated onto the sample 1.

The inspection module 200 may serve to inspect for electrical defects in a sample 1 by detecting an electrical potential change occurring on a surface of the sample 1.

The inspection module 200 may include a scanner 210 that scans the sample 1, and an analyzer 220 that detects an emission electron signal emitted from the sample 1 during scanning by the scanner 210, and analyzes a change in surface potential of the sample 1. Furthermore, it may include an image generator 230 that converts a signal analyzed in the analyzer 220 to generate an image, and an evaluator 240 that determines whether the sample 1 has an electrical defect using the generated image. For example, the surface potential may be represented as a pixel intensity of the generated image and evaluator 240 may compare the generated image to an existing image to find pixels having an abnormal intensity. Or, in another example, the evaluator 240 may flag pixels having an intensity that exceeds a threshold intensity or fail to reach a threshold intensity. The evaluator 240 may be implemented by or in combination with a controller or other computing device.

As explained above, the evaluator 240 can assess that an electrical defect has occurred in a specific area on the image if an abnormal change in the potential is observed in that area. The determination of defect presence can also be made by an automated algorithm.

A process of the inspection module 200 scanning and determining electrical defects in the sample 1 may be common to existing equipment (e.g., may implement a conventional scanning process), so a description thereof may be omitted.

FIGS. 5A and 5B illustrate views for describing a process of inspecting a sample for defects using the pulse electron microscope device according to FIG. 1.

FIG. 5A illustrates a surface potential of the sample 1 that changes depending on a timing at which the first electron pulse E1 and the second electron pulse E2 irradiate the sample 1.

(i), (ii), and (iii) of FIG. 5B show results of determining whether each inspection indicates anormal or defective area of the sample (e.g., a contact of a semiconductor device) in (i), (ii), and (iii) of FIG. 5A. In the remaining description, the inspection area of a sample may be referred to as a contact, with the understanding that the described embodiments may be applicable to other inspection areas of a semiconductor device.

First, in FIG. 5A, (I) shows that the second electron pulse E2 is first irradiated and focused on the sample 1, and (II) shows that after a certain time t1 has passed after the second electron pulse E2 is focused on and irradiates the sample 1, the first electron pulse E1 is focused on and irradiates the sample 1. (III) shows a potential difference occurring on the surface of the sample 1 according to time and shows a time point when the second electron pulse E2 and the first electron pulse E1 are focused on the sample 1. The change in surface potential may vary depending on a characteristic time of the circuit connected to a contact or semiconductor device. In each case, a point may occur where the change in surface potential is at a maximum, and in (III) , a time point where the change in surface potential is at a maximum is indicated as p.

First, the change in surface potential may occur by the action of the second electron pulse E2 incident on and irradiating the sample 1. Such a change may have long-term effects on charging, such that a charge may linger, potentially affecting a future measurement.

The first electron pulse E1 is incident on the sample 1 following the second electron pulse E2 by a time interval Δt (expressed as t1). t1 may correspond to a time between the second electron pulse E2 being incident on the target and the time point p, which corresponds to a maximum change in surface potential resulting from the action of the second electron pulse E2.

The interval controller 150 may control the time interval Δt such that the first electron pulse E1 is focused on the sample 1 at the time point p when the change in surface potential of the sample 1 by the action of the second electron pulse E2 is at a maximum.

A purpose of the interval controller 150 may be to focus the first electron pulse E1 on the sample 1 at the time point p when the defect contrast of the sample 1 is at its maximum from the second electron pulse, and the time interval Δt may be fixed to a specific time t1 as shown in FIG. 5.

The inspection module 200 may scan the sample with the interval controller 150 fixing the time interval Δt between the first electronic pulse E1 and the second electronic pulse E2 at t1 as described above, which may result in an improved signal capable of distinguishing between a defective contact and a normal contact and which may be obtained at a greater speed.

In FIG. 5, (i), (ii), and (iii) represent changes in surface potential when the first electron pulse E1 and the second electron pulse E2 are incident on three different contacts. For example, (i), (ii), and (iii) may each represent a result of inspecting a respective contact while fixing the time interval Δt between the first electron pulse E1 and the second electron pulse E2 to t1.

FIG. 5B illustrates an image showing whether each contact according to FIG. 5A is normal or defective. Referring to FIG. 5A and FIG. 5B, it may be confirmed that the defect contrast is high in the inspection corresponding to (i) and (iii). Thus, the contacts may indicate that the tested contacts are normal. In comparison, (ii) shows a result of testing that the contact is defective.

The inspection process illustrated in FIG. 5 is an example of a case where the inspection is performed by setting a pulse repetition rate (the rate at which the source laser pulse repeats) and a scan rate, which is the speed at which the scanner 210 of the inspection module 200 obtains pixels, to be the same. When setting the pulse repetition rate and the scan rate in this way, measurements may be taken using one pulse per pixel.

When the pixel size is set to be the same as the contact size, measurements may be performed with one pulse per contact, which results in minimizing the long-term impact on charging mentioned above and increasing the rate of the high-speed inspection.

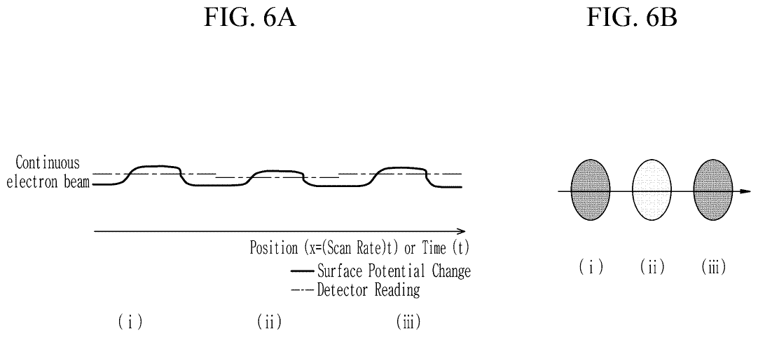

FIGS. 6A and 6B illustrate views for describing a process of inspecting a sample for defects using a conventional pulse electron microscope device.

For purposes of comparison, the contacts subject to inspection in (i), (ii), and (iii) of FIG. 6A are the same as the contacts subject to inspection in (i), (ii), and (iii) of FIG. 5A ((i) normal, (ii) defective, (iii) normal).

FIG. 6B shows whether the contact according to FIG. 6A is normal or defective. This illustrates results of determining whether a product is defective using a conventional electron microscope device, and it is illustrated to describe the difference from the determination result in FIG. 5B according to the present disclosure.

FIG. 6A corresponds to (III) shown in FIG. 5A.

Referring to FIG. 6A, a continuous electron beam used in a conventional electron microscope device is illustrated. When determining a signal detected at each contact, it may be confirmed that the signal is small compared to (III) of FIG. 5A.

This may be a result of using a continuous electron beam to obtain the measurement shown in FIG. 6A. Because focusing and charging of the sample 1 may be performed together while passing across each contact of (i), (ii), and (iii), the signal detected at each contact becomes smaller.

Referring to FIG. 6B, as in (i) and (iii) of FIG. 5B, the defect contrast is shown to be high in (i) and (iii) of FIG. 6B.

However, in (ii) of FIG. 6B, unlike (iii) of FIG. 5B, it may be confirmed that an average image appears. As a result, when using a conventional electron microscope device, (ii) there is a risk that the presence or absence of contact defects may not be accurately inspected.

FIG. 7 illustrates a view for describing a process of inspecting a sample for defects using the pulse electron microscope device according to FIG. 3.

In FIG. 5, a process is illustrated in which the pulse repetition rate and the scan rate, which is the speed at which the inspection module 200 obtains pixels, are set to be the same. Measurement may be performed with one pulse per contact by setting the pixel size to be the same as the contact size.

In contrast, FIG. 7 illustrates an example in which the pulse repetition rate higher is set higher than the scan rate, and unlike in FIG. 5, one contact may be measured with multiple pulses.

However, in this case as well, in order to minimize a long-term effect on charging, the synchronizer 160 may irradiate the sample 1 with the fourth laser pulse L4.

In FIG. 7, (I) indicates that the second electron pulse E2 first irradiate the sample 1, and (II) indicates that after the second electron pulse E2 is focused on the sample 1, after a certain time t1 has passed, the first electron pulse E1 is focused on and irradiates the sample 1.

(III) indicates that the synchronizer 160 causes the fourth laser pulse L4 to be focused on and irradiate the sample 1, and referring to (IV) , a time point at which the fourth laser pulse L4 is focused on the sample 1 is t2.

Referring to (III) , the synchronizer 160 may cause the fourth laser pulse L4 to be focused on and irradiate the same area of the sample 1 where the first electron pulse E1 is focused a certain period of time after the first electron pulse E1 irradiates the sample 1.

(IV) indicates a potential change occurring on the surface of the sample 1 as the second electron pulse E2, the first electron pulse E1, and the fourth laser pulse L4 are focused on and irradiate the sample 1.

Referring to the potential change of (IV) , the fourth laser pulse L4 may discharge the surface of the sample 1 to maintain a surface potential of the sample 1 to be constant after the fourth laser pulse L4, but before a subsequent second electron pulse E2 irradiates the sample again.

For example, as the fourth laser pulse irradiates the sample 1, the sample 1 may have a same surface potential at each time point when second electron pulses E2 are focused on and irradiate the sample 1 (potential homogenization).

Among the graphs shown in (IV) , as a result according to a Normal line, (a) the contact is normal, and as a result according to a Defect line, (b) the contact is defective.

As described above, FIG. 7 illustrates a process in which the pulse repetition rate is set higher than the scan rate, and FIG. 7 includes a synchronizer 160 for controlling the surface potential.

In some embodiments, the pulse electron microscope device 100 according to the present disclosure may perform an inspection by fixing a time interval Δt between the first electron pulse E1 and the second electron pulse E2 to t1 using the interval controller 150. Accordingly, a signal noise ratio (SNR) may increase, enabling the examination of minute changes in Resistance, Capacitance, and Reactance. In such embodiments, even if there is no potential equalization effect by the synchronizer 160, there may be an effect of increasing the defect contrast.

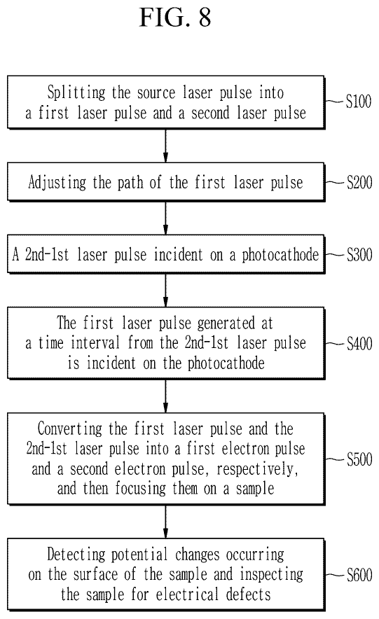

FIG. 8 illustrates a flow diagram describing an inspection method using the pulse electron microscope device according to FIG. 1.

Referring to FIG. 8, an inspection method using the pulse electron microscope device 100 according to the present disclosure may include an operation S100 in which the source laser pulse L emitted from the pulse generator 110 is split into the first laser pulse L1 and the second laser pulse L2 by the first beam splitter 120, an operation S200 in which the interval controller 150 controls an optical path length of the first laser pulse L1, an operation S300 in which the second laser pulse L2 is partially reflected by the second beam splitter 130 and the resulting second-1 laser pulse L2-1 is incident on the photocathode 142, an operation S400 in which the first laser pulse L1 that has passed through the interval controller 150 is incident on the photocathode 142 with a time interval Δt after the second-1 laser pulse L2-1, an operation S500 in which the photocathode 142 converts the first laser pulse L1 and the second-1 laser pulse L2-1 into the first electron pulse E1 and the second electron pulse E2, respectively, and focuses the electron pulses on the sample 1, and an operation S600 in which the inspection module 200 detects a potential change occurring on a surface of the sample 1 as a result of the electron pulses during a process of scanning the sample 1 and inspects the electrical defect of the sample 1.

The inspection method according to the present disclosure is different from a conventional defect inspection method using electron beams, which could only detect severe defects such as complete circuit disconnection, in that it can detect a defect that has occurred without being limited to a degree of disconnection of the defect by utilizing a photocathode and two laser pulses.

In particular, the time interval between the first electron pulse E1 and the second electron pulse E2 may be adjusted according to a scanning speed of the inspection module 200 by using the interval controller 150, so the inspection speed may also be adjusted as needed. Accordingly, by fixing the time interval between pulses, high-speed inspection may be possible without speed reduction compared to inspection using conventional electron beams.

Furthermore, the inspection method according to the present disclosure is significant in that inspection is possible to scan at a higher speed by setting the pulse repetition rate and the scan rate to be the same.

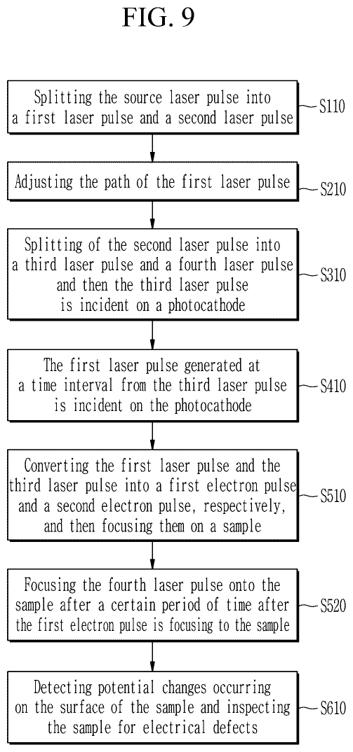

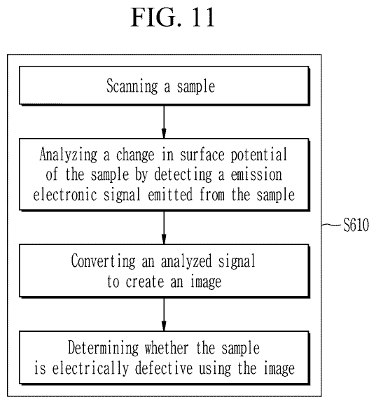

FIG. 9 to FIG. 11 illustrate views for describing an inspection method using the pulse electron microscope device according to FIG. 3.

Referring to FIG. 9, an inspection method using the pulse electron microscope device 100 according to the present disclosure may include an operation S110 in which the source laser pulse L emitted from the pulse generator 110 is split into the first laser pulse L1 and the second laser pulse L2 by the first beam splitter 120, an operation S210 in which the interval controller 150 controls an optical path length of the first laser pulse L1, an operation S310 in which the second beam splitter 130 splits the second laser pulse L2 into the third laser pulse L3 and the fourth laser pulse L4, and the split third laser pulse L3 is reflected by the second beam splitter 130 and is incident on the photocathode 142, an operation S410 in which the first laser pulse L1 that has passed through the interval controller 150 is incident on the photocathode 142 at a time interval Δt after the third laser pulse L3, an operation S510 in which the photocathode 142 converts the first laser pulse L1 and the third laser pulse L3 into the first electron pulse E1 and the second electron pulse E2, respectively, and focuses the electron pulses on the sample 1, an operation S520 in which the synchronizer 160 focuses the fourth laser pulse L4, which has passed through the second beam splitter 130, on the same area of the sample 1 where the first electron pulse E1 was focused a certain time after the first electron pulse E1 irradiated the sample 1, and an operation S610 in which the inspection module 200 detects a potential change occurring on a surface of the sample 1 during a process of scanning the sample 1 resulting from the electron pulses and inspects the electrical defect of the sample 1.

The inspection method according to the present disclosure may maintain the surface potential difference of the sample 1 through operation S520, in which fourth laser pulse L4 of the synchronizer 160 discharges the surface of the sample 1 such that a surface potential difference of the sample 1 is maintained constant when the second electron pulse E2 irradiates the sample 1 again, thereby making the surface potential uniform.

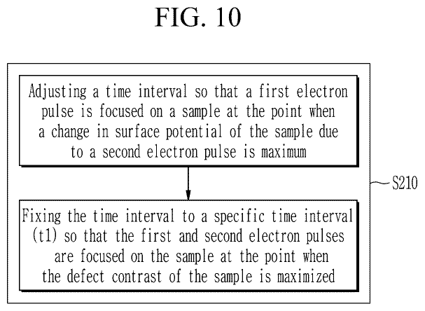

The operation S210 in which the optical path length of the split and incident first laser pulse L1 is controlled may include an operation of adjusting the time interval Δt such that the first electron pulse E1 is focused on and irradiates the sample 1 at a time point when a change in surface potential of the sample 1 by the action of the second electron pulse E2 becomes maximum, and an operation of fixing the time interval Δt to a specific time t1 such that the first electron pulse E1 and the second electron pulse E2 are focused on the sample 1 at a time point when the defect contrast of the sample 1 is maximized, by the interval controller 150 (see FIG. 10).

The operation S610 in which the electrical defect of the sample 1 is inspected may include an operation in which the scanner 210 scans the sample 1, an operation in which the analyzer 220 detects an emission electronic signal emitted from the sample 1 during the scanning process and analyzes a change in surface potential of the sample 1, an operation in which the image generator 230 converts a signal analyzed by the analyzer 220 to generate an image, and an operation in which the evaluator 240 determines whether or not the sample 1 is electrically defective using the generated image.

The inspection method according to the present disclosure may further include an operation in which the pulse controller 112 controls an amount of charge of the source laser pulse L emitted from the pulse generator 110, thereby maximizing the defect contrast of the sample 1.

As described above, the inspection method according to the present disclosure may further include an operation of setting a pulse repetition and a scan rate to be the same. In some embodiments, measurement is performed with 1 pulse per pixel, and if the pixel size is set to the same size as the sample 1 (semiconductor device or contact), one pulse may be measured per contact. As a result, a time-dependent effect of charging may be minimized, and multiple contacts in the semiconductor may be inspected at a high speed.

If an inspection purpose is high throughput, it may be desirable to proceed by setting the pulse repetition rate and the scan rate to be the same and matching the pixel size to the contact size.

If the inspection purpose is high sensitivity, it may be desirable to set the pulse repetition rate higher than the scan rate so that one contact may be measured with multiple pulses. In this process, the scan rate may be set lower than the pulse repetition rate until sufficient defect contrast is secured. In this case, a surface potential difference may be made uniform by the synchronizer 160.

However, as the interval controller 150 fixes time interval (Δt) values of the first electron pulse E1 and the second electron pulse E2 to t1 and then performs the inspection, the signal noise ratio (SNR) may increase, so even if the synchronizer 160 does not make the surface potential uniform, the defect contrast may appear high.

According to an inspection method using a pulse electron microscope device 100 according to the present disclosure, inspection based on semiconductor electrical characteristics can be performed by setting the pulse repetition rate and the scan rate differently depending on the inspection purpose.

Furthermore, by measuring a contact defect during the inspection process, the time interval Δt between the first electron pulse E1 and the second electron pulse E2 at which the defect contrast is maximized may be found, and then the inspection may be performed while the interval controller 150 is fixed to the time t1 corresponding to the time interval. When scan is performed while the interval controller 150 fixes the time interval Δt between the first electronic pulse E1 and the second electronic pulse E2 to t1 as described above, the maximum signal capable of distinguishing between a defective contact and a normal contact may be obtained at a maximum speed.

When inspection is performed using a conventional electron microscope, an average response of the electron beam being irradiated may be recorded for a time period of more than 10⁻⁹ s per pixel, which poses a problem in that a time difference between charging and measurement is not accurately distinguished. Furthermore, there was a limitation that a time resolution was limited to a speed of the inspection device, so that only changes in electrical characteristics slower than 1 GHz could be detected.

In contrast, when inspection is performed using a pulse electron microscope device 100 according to the present disclosure, response can be recorded with a time resolution of within 10⁻¹¹ s between charging and measurement. Furthermore, it may have an advantage of being able to reach up to 100 GHz level as the time resolution is limited to a width of an electron pulse. Herein, the width of the electron pulse refers to a temporal width of the pulse, which is a factor determined by the characteristics of the laser source and the photocathode.

While this disclosure has been described in connection with what is presently considered to be practical embodiments, it is to be understood that the inventive concept is not limited to the disclosed embodiments, but, on the contrary, is intended to cover various modifications and equivalent arrangements.

What is claimed is:

1. A pulse electron microscope device comprising:
a pulse generator configured to emit a source laser pulse;
a first beam splitter configured to split the source laser pulse into a first laser pulse and a second laser pulse;
a second beam splitter configured to split the second laser pulse to result in a second-1 laser pulse, which is included in the second laser pulse;
an interval controller configured to control a time interval between the first laser pulse and the second-1 laser pulse by controlling an optical path length of the first laser pulse;
a column part including a photocathode, the photocathode configured to convert the first laser pulse into a first electron pulse and convert the second-1 laser pulse into a second electron pulse, and the column part configured to focus the first electron pulse and the second electron pulse onto a sample; and
an inspection module configured to identify electrical defects in the sample by detecting a change in potential occurring on a surface of the sample as a result of the first electron pulse and the second electron pulse.

2. The pulse electron microscope device of claim 1, wherein
the interval controller is configured to control the time interval such that the first electron pulse is focused on and irradiated on the sample at a time point after the second electron pulse is focused on and irradiated on the same when a change in surface potential of the sample resulting from the second electron pulse reaches a maximum.

3. The pulse electron microscope device of claim 1, wherein
the interval controller is configured to fix the time interval to a time at which the first electron pulse and the second electron pulse are focused on the sample at a time point when a defect contrast of the sample is maximized.

4. The pulse electron microscope device of claim 1, further comprising a pulse controller configured to control an amount of charge of the source laser pulse emitted from the pulse generator.

5. The pulse electron microscope device of claim 1, wherein
the interval controller is positioned in an optical path of the first laser pulse.

6. The pulse electron microscope device of claim 1, wherein
the interval controller includes a reflector configured to control the optical path length of the first laser pulse by reflecting the first laser pulse.

7. The pulse electron microscope device of claim 6, wherein
a plurality of reflectors are arranged in the interval controller, and the reflectors are configured so that their positions are adjustable.

8. A pulse electron microscope device comprising:
a pulse generator configured to emit a source laser pulse;
a first beam splitter configured to split the source laser pulse into a first laser pulse and a second laser pulse;
a second beam splitter configured to split the second laser pulse into a third laser pulse and a fourth laser pulse;
a column part including a photocathode that converts the first laser pulse into a first electron pulse and converts the third laser pulse into a second electron pulse and configured to focus the first electron pulse and the second electron pulse on a sample;
an interval controller configured to cause the first laser pulse to be incident on the photocathode and control an optical path length of the first laser pulse to cause a delay for a time that the first laser pulse is incident on and irradiates the photocathode such that the first electron pulse is focused on and irradiates the sample at a time point when a change in surface potential of the sample as a result of the second electron pulse is at a maximum;
a synchronizer configured to focus the fourth laser pulse onto the sample; and
an inspection module configured to identify electrical defects in the sample by detecting a change in potential occurring on a surface of the sample as a result of the first electron pulse and the second electron pulse.

9. The pulse electron microscope device of claim 8, wherein
the synchronizer causes the fourth laser pulse to be focused on the same area of the sample where the first electron pulse was focused after a set period of time after the first electron pulse irradiated the sample.

10. The pulse electron microscope device of claim 8, wherein
the inspection module includes:
a scanner configured to scan the sample; and
an analyzer configured to analyze a change in surface potential of the sample by detecting an emission electron signal emitted from the sample during a scanning process of the scanner.

11. The pulse electron microscope device of claim 10, further comprising:
an image generator configured to convert a signal analyzed in the analyzer to generate an image; and
an evaluator configured to determine whether the sample has an electrical defect using the generated image.

12. An inspection method comprising:
splitting, by a first beam splitter, a source laser pulse emitted from a pulse generator into a first laser pulse and a second laser pulse;
adjusting, by an interval controller, an optical path length of the first laser pulse;
splitting, by a second beam splitter, the second laser pulse into a third laser pulse and a fourth laser pulse, and reflecting, by the second beam splitter, the third laser pulse to be incident on a photocathode;
causing a first laser pulse passing through the interval controller to be incident on and irradiate the photocathode at a set time interval from when the third laser pulse irradiates the photocathode;
converting, by the photocathode, the first laser pulse and the third laser pulse into a first electron pulse and a second electron pulse, respectively, and focusing them on a sample; and
inspecting an electrical defect in the sample by detecting a change in potential occurring on a surface of a sample during a process of scanning the sample.

13. The inspection method of claim 12, further comprising
controlling the set time interval such that the first electron pulse is focused on and irradiates the sample at a time point when a change in surface potential of the sample caused by the second electron pulse reaches a maximum.

14. The inspection method of claim 12, further comprising
fixing the set time interval to a specific time such that the first electron pulse and the second electron pulse are each focused on and irradiate the sample at a time point when a defect contrast of the sample is maximized.

15. The inspection method of claim 12, wherein
the inspecting of the electrical defects of the sample includes:
scanning the sample;
analyzing a change in surface potential of the sample by detecting an emission electron signal emitted from the sample during a scanning process;
converting a signal analyzed in the analyzer to generate an image; and
determining whether the sample has an electrical defect using the generated image.

16. The inspection method of claim 12, further comprising
setting a pulse repetition rate of the source laser pulse and a scan rate, which is a speed at which a scanner obtains pixels, to be the same.

17. The inspection method of claim 12, further comprising setting a pulse repetition rate higher than a scan rate.

18. The inspection method of claim 12, further comprising
focusing the fourth laser pulse onto the sample.

19. The inspection method of claim 18, further comprising
causing the fourth laser pulse to be focused on a same area of the sample where the first electron pulse was focused after a certain period of time after the first electron pulse was irradiated onto the sample.

20. The inspection method of claim 12, further comprising
maximizing defect contrast of the sample by controlling an amount of charge of the source laser pulse emitted from the pulse generator.
